(19) United States
(12) Patent Application Publication
(10) Pub. No.: US 2015/0349491 A1
(43) Pub. Date: Dec. 3, 2015

(54) DISTRIBUTED BRAGG REFLECTOR RIDGE LASER DIODE AND FABRICATING METHOD THEREOF

(71) Applicant: ELECTRONICS AND TELECOMMUNICATIONS RESEARCH INSTITUTE, Daejeon (KR)

(72) Inventors: Oh Kee KWON, Daejeon (KR); Su Hwan OH, Daejeon (KR); Chul Wook LEE, Daejeon (KR)

(73) Assignee: ELECTRONICS AND TELECOMMUNICATIONS RESEARCH INSTITUTE, Daejeon (KR)

(21) Appl. No.: 14/601,780

(22) Filed: Jan. 21, 2015

(30) Foreign Application Priority Data
Jun. 3, 2014 (KR) 10-2014-0067632

(51) Int. Cl. H01S 5/125; H01S 5/028; H01S 5/20; H01S 5/22; H01S 5/042

(52) U.S. Cl. CPC H01S 5/125; H01S 5/22; H01S 5/0421; H01S 5/2031; H01S 5/0285; H01S 5/0282; H01S 5/0425

(57) ABSTRACT

Provided herein is a distributed bragg reflector ridge laser diode that is capable of easily embodying a diffraction grating and that minimizes an optical absorption effect on a DBR area, and a fabricating method thereof, the distributed bragg reflector ridge laser diode including a lower clad layer formed on top of a substrate; an active core zone formed on top of the lower clad layer; a plurality of ridge wave guides formed on top of the active core zone such that they are spaced from one another and extend in an axial direction; and a diffraction grating formed on top of the active core zone and between the plurality of ridge wave guides.

### CROSS-REFERENCE TO RELATED APPLICATION

The present application claims priority to Korean patent application number 10-2014-0067632, filed on Jun. 3, 2014, the entire disclosure of which is incorporated herein in its entirety by reference.

### BACKGROUND

1. Field of Invention

Various embodiments of the present invention relate to a distributed bragg reflector ridge laser diode and fabricating method thereof, and more particularly, to a distributed bragg reflector ridge laser diode that is capable of easily embodying a diffraction grating and that minimizes an optical absorption effect on a DBR area, and a fabricating method thereof.

2. Description of Related Art

In general, a red color semiconductor single mode laser diode having a working wavelength of 650 nm has a peripheral layer made of a material having a high specific gravity of aluminum. Therefore, in the case of reclaiming a diffraction grating near an active zone through a regrowing process, the element transference number becomes extremely low due to oxidization of the aluminum. Furthermore, since it is difficult to regrow material layers on gain areas and DBR (Distributed Bragg Reflector) areas, it is difficult to embody them in different material groups, which is a problem. Recently, cases have been reported where a diffraction grating layer is embodied on a surface of an element, where a DBR active zone and a gain area are embodied with a same material, where the cycle of a diffraction grating relates to a working wavelength based on bragg conditions, and where a diffraction grating of a high order mode is used to embody a smooth diffraction grating cycle.

FIG. 1 is a side view of a conventional DBR-LD (Distributed Bragg Reflector—Laser Diode), illustrating a side (y-z surface) of an element (x: lateral direction, y: longitudinal direction, z: axial direction). Such a conventional distributed bragg reflector laser diode includes a substrate 10, lower clad layer 20, lower wave guide 30, active zone 40, upper wave guide 50, upper clad layer 60, and cap layer 70. Such a conventional distributed bragg reflector laser diode consists of a gain (active) area that creates light in an axial direction (z direction) and a DBR area where a diffraction grating A is formed. Furthermore, on the gain (active) area, light is created on the active zone 40 as current is injected into the cap layer 70 made of p-GaAs material. Herein, the light is created as wave guide light by the lower wave guide 30 and the upper wave guide 50. The wave guide light goes through a process of reflecting only light of a certain wavelength as it passes the diffraction grating A formed on the DBR area, wherein the wave guide light is reflected by a coating surface (not illustrated) formed on a left cross-section of the element and a diffraction grating A formed on an upper right end and goes through a round-trip process to operate as a resonator.

Such a conventional distributed bragg reflector laser diode aforementioned has several problems in terms of fabricating and structure thereof.

First of all, it requires a process of etching the cap layer (p-GaAs) 70, upper clad layer (p-AlGaAs) 60, and upper wave guide (p-AlGaInP) 50 in order to form a diffraction grating A on a DBR area, but it is difficult to embody a diffraction grating of good quality due to differences in etching rates and changes in etching forms for heteromaterials. Furthermore, in the case of etching the upper clad layer 60, due to reduction of layer thickness, the form of the wave guide may be severely distorted, which is a problem. Furthermore, in the case of embodying a diffraction grating A of a high order mode, radiation modes of low orders are mainly formed in y-z direction, and thus reflecting of the radiation modes may increase noise output and reduce the diffraction grating efficiency.

Secondly, an active zone refractive index of the DBR area must be changed for adjustment of single mode characteristics and for wavelength conversion, and just as in a general gain area, an oscillating wavelength may be changed by injecting current into the cap layer 70. In a conventional structure, since it is difficult to sufficiently planarize a diffraction grating formed by deep etching with an insulating film, a portion of the wave guide light may contact a pad metal surface, which would increase light loss, and due to the reflecting on the metal surface, it would become difficult to obtain smooth wave guide characteristics and good spectrum characteristics. Furthermore, due to the increase of resistance caused by p-GaAs material partially formed on the cap layer 70, it is difficult to obtain smooth wavelength conversion characteristics, and further, optical output would change according to wavelength conversion due to additional light created by injection of current.

Thirdly, since in a conventional structure, a wave guide core layer on a DBR area uses an active zone as it is, the optical absorption that occurs on the active zone would increase the loss of DBR area.

Due to the aforementioned problems, in the case of a conventional red DBR-LD, the high loss rate of the DBR area would make oscillation at room temperature difficult, and cause a low side mode suppression ratio at the oscillation spectrum.

### SUMMARY

Various embodiments of the present invention are directed to a distributed bragg reflector laser diode that is capable of easily embodying a diffraction grating without the problems that used to be caused by etching a clad layer.

Furthermore, various embodiments of the present invention are also directed to minimize an optical absorption effect that occurs when a light created on a gain area penetrates a DBR area.

Furthermore, various embodiments of the present invention are also directed to embody a laser diode capable of causing small loss and a high diffraction efficiency based on no significant change in a wave guide mode, and to embody a laser diode having a room temperature oscillation, low oscillation inception current, and high optical output characteristics.

One embodiment of the present invention provides a distributed bragg reflector ridge laser diode including: a lower clad layer formed on top of a substrate; an active core zone formed on top of the lower clad layer; a plurality of ridge wave guides formed on top of the active core zone such that they are spaced from one another and extend in an axial direction; and a diffraction grating formed on top of the active core zone and between the plurality of ridge wave guides.

Herein, an etching stopping layer may be formed on top of the active core zone, and the plurality of ridge wave guides and diffraction grating may be formed on top of the etching stopping layer.

Herein, a middle clad layer may be formed between the active core zone and etching stopping layer.

Herein, the distributed bragg reflector ridge laser diode may further include a contact layer formed on top of the plurality of ridge wave guides.

Herein, the contact layer may include a grating on a location corresponding to a location of the diffraction grating.

Herein, the active core zone may include a first core layer, active zone, and second core layer formed successively in the axial direction, the first core layer and second core layer being made of a material having a greater band gap than the active zone.

Herein, a COD (Catastrophic Optical Damage) area may be formed on top of at least one of the plurality of ridge wave guides corresponding to the location of the second core layer.

Herein, an anti-reflector coating film may be formed on a side of an axial direction of where the first core layer is formed.

Herein, a coating film having a predetermined reflectivity may be formed on a side of an axial direction of where the second core layer is formed.

Herein, an electrode may be formed on top of the plurality of ridge wave guides and below the substrate.

Another embodiment of the present invention provides a method for fabricating a distributed bragg reflector ridge laser diode, the method including forming a lower clad layer on top of a substrate, and forming an active core zone on top of the lower clad layer to form a multilayer structure; forming a plurality of ridge wave guides on top of the active core zone such that they are spaced from one another and extend in an axial direction; and forming a diffraction grating between the plurality of ridge wave guides on top of the active core zone.

Herein, the active core zone may include a first core layer, active zone and second core layer formed successively in the axial direction, and the first core layer and second core layer may be formed as a material having a greater band gap than the active zone is injected after the forming of the ridge wave guide and forming of the diffraction grating.

Herein, a COD (Catastrophic Optical Damage) area may be formed on top of at least one of the plurality of ridge wave guides corresponding to the location of the second core layer.

Herein, the method may further include forming an anti-reflector coating film on a side of an axial direction of where the first core layer is formed.

Herein, the method may further include forming a coating film having a predetermined reflectivity on a side of an axial direction of where the second core layer is formed.

Herein, the forming of a ridge wave guide and the forming of the diffraction grating may be performed at the same time.

Herein, the forming of a ridge wave guide and the forming of a diffraction grating may include forming an etching stopping layer on top of the active core zone; forming an upper clad layer on top of the etching stopping layer; forming a contact layer on top of the upper clad layer; forming a grating of a grating shape on top of the contact layer; and forming the ridge wave guide and diffraction grating by etching the grating, contact layer, and upper clad layer.

Herein, the method may further include forming a middle clad layer on top of the active core zone prior to the forming of an etching stopping layer.

Herein, the method may further include forming a passivation layer on top of the ridge wave guide and diffraction grating.

Herein, the method may further include forming an electrode on top of the plurality of ridge wave guides and below the substrate.

According to various embodiments of the present invention, it is possible to embody a distributed bragg reflector laser diode that is capable of easily embodying a diffraction grating without the problems that used to be caused by etching a clad layer (distortion of wave guide light on a DBR area, reflecting of radiation mode when embodying a diffraction grating of a high order mode, loss and reflecting due to a metal-pad on top of the DBR area, and increase of resistance).

Furthermore, according to various embodiments of the present invention, it is possible minimize an optical absorption effect that occurs when light created on a gain area penetrates a DBR area by changing the material of the active zone of the DBR area into a material having a greater band gap than the core layer of the gain area.

Furthermore, according to various embodiments of the present invention, it is possible to embody a laser diode capable of causing small loss and a high diffraction efficiency based on no significant change in a wave guide mode, and to embody a laser diode having a room temperature oscillation, low oscillation inception current, and high optical output characteristics.

### BRIEF DESCRIPTION OF THE DRAWINGS

The above and other features and advantages of the present invention will become more apparent to those of ordinary skill in the art by describing in detail exemplary embodiments with reference to the attached drawings in which:

FIG. 1 is a side view of a conventional distributed bragg reflector laser diode;

FIG. 2 is a perspective view of a distributed bragg reflector laser diode according to an embodiment of the present invention;

FIG. 3 is a flowchart for explaining a method for fabricating a distributed bragg reflector ridge laser diode according to an embodiment of the present invention;

FIGS. 4 to 13 are views for explaining a method for fabricating a distributed bragg reflector ridge laser diode according to an embodiment of the present invention.

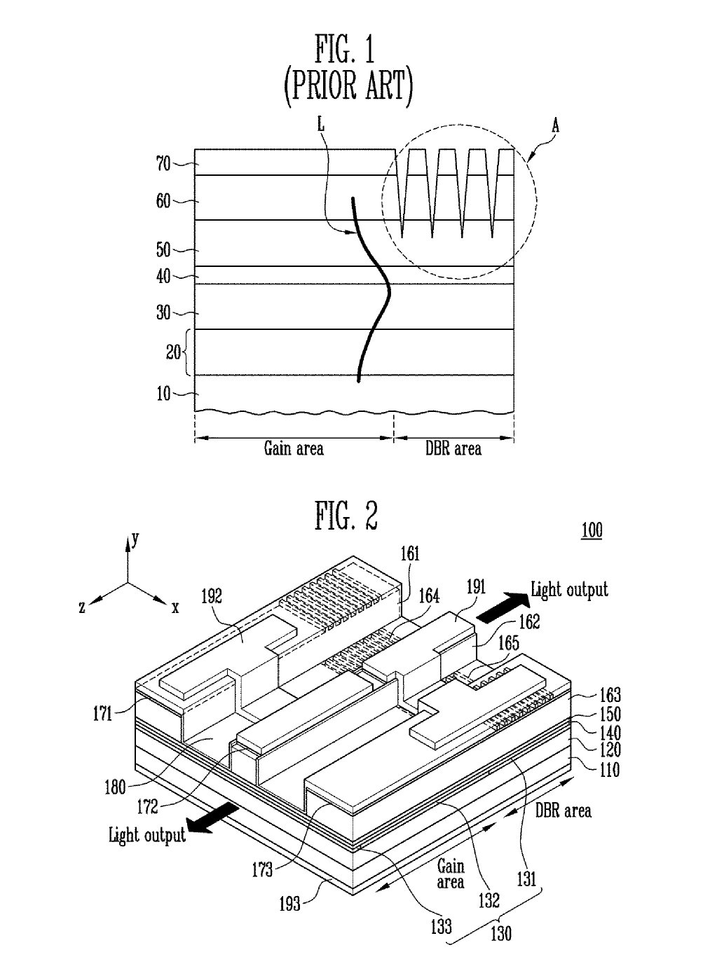

### DETAILED DESCRIPTION

Hereinafter, exemplary embodiments will be described in greater detail with reference to the accompanying drawings. Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may include deviations in shapes that result, for example, from manufacturing. In the drawings, lengths and sizes of layers and regions may be exaggerated for clarity. Like reference numerals in the drawings denote like elements. It is also understood that when a layer is referred to as being “on top of” another layer or substrate, it can be directly on the other or substrate, or intervening layers may also be present.

In this specification, a singular form may include a plural form as long as it is not specifically mentioned in a sentence. Furthermore, ‘include/comprise’ or ‘including/comprising’ used in the specification represents that one or more components, steps, operations, and elements exist or are added.

Hereinbelow, a structure of a distributed bragg reflector ridge laser diode according to an embodiment of the present invention will be explained.

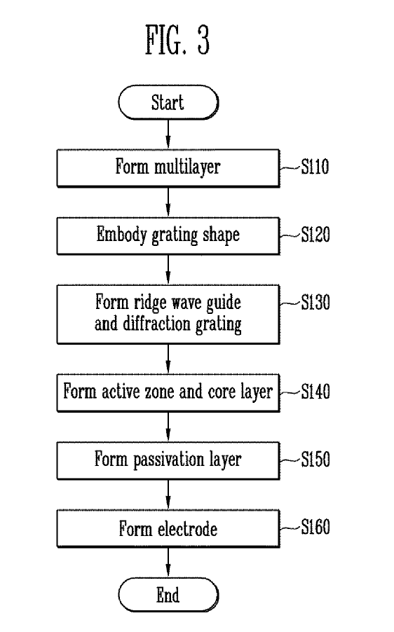

FIG. 2 is a perspective view of a distributed bragg reflector ridge laser diode according to an embodiment of the present invention.

Referring to FIG. 2, a distributed bragg reflector ridge laser diode according to an embodiment of the present invention 100 includes a substrate 110, lower clad layer 120, active core zone 130, a plurality of ridge wave guides 161, 162, 163, and a plurality of diffraction gratings 164, 165. Furthermore, the distributed bragg reflector ridge laser diode 100 may include a middle clad layer 140, etching stopping layer 150, a plurality of contact layers 171, 172, 173, passivation layer 180, and a plurality of electrodes 191, 192, 193.

The substrate 110 may be forms as an n-GaAs layer.

The lower clad layer 120 is formed on top of the substrate 110. The lower clad layer may be a buffer and n-clad layer that includes AlGaInP.

The active core zone 130 is formed on top of the lower clad layer 120.

The active core zone 130 includes a first core layer 131, active zone 132, and second core layer 133. Herein, in an axial direction (z axis), the second core layer 133 is formed first, then followed by the active zone 132, then followed by the first core layer 131.

The middle clad layer 140 is formed on top of the active core zone 130. Herein, the middle clad layer 140 may include AlGaInP.

The etching stopping layer 150 is formed on top of the active core zone 130 and the middle clad layer 140. Herein, the etching stopping layer 150 may include InGaP.

A plurality of ridge wave guides 161, 162, 163, that is a first ridge wave guide 161, second ridge wave guide 162, and third ridge wave guide 163 are formed on top of the active core zone 130. More particularly, the first ridge wave guide 11, second ridge wave guide 162, and third ridge wave guide 163 are formed on top of the etching stopping layer 150 such that they are spaced from one another and extend in an axial direction. Herein, the plurality of ridge wave guides 161, 162, 163 may include AlGaInP or AlGaAs.

Furthermore, on top of at least one of the plurality of ridge wave guides 161, 162, 163, there may be formed a COD (Catastrophic Optical Damage) area where the plurality of contact layers 171, 172, 173 and plurality of electrodes 191, 192, 193 that will be explained hereinafter are not formed on an area corresponding to the location of the second core layer 131. The width of each of the plurality of ridge wave guides 161, 162, 163 determine x axis mode characteristics, and may embody a lateral direction single mode in or below 7 μm.

A plurality of diffraction gratings 164, 165, that is a first diffraction grating 164 and second diffraction grating 165 are formed on top of the active core zone. More specifically, the first diffraction grating 164 and second diffraction grating 165 are formed on top of the etching stopping layer 150, and may be formed between the plurality of ridge wave guides 161, 162, 163. By these plurality of diffraction gratings 164, 165, the thickness of the clad layer near the plurality of ridge wave guides 161, 162, 163 is modulated. The plurality of diffraction gratings 164, 165 may be made of a same material as the plurality of ridge wave guides 161, 162, 163.

Each of the plurality of contact layers 171, 172, 173, that is the first contact layer 171, second contact 172, and third contact layer 173 are formed on top of the first ridge wave guide 161, second ridge wave guide 162, and third ridge wave guide 163, respectively. Furthermore, on top of each of the first contact layer 171, second contact layer 172, and third contact layer 173, a first diffraction grating 171a, second diffraction grating 172a, and third diffraction grating 173a are formed on corresponding locations of the plurality of diffraction gratings 164, 165, respectively.

The passivation layer 180 is formed on top of the plurality of ridge wave guides 161, 162, 163, plurality of diffraction gratings 164, 165, and plurality of contact layers 171, 172, 173.

Of the plurality of electrodes 191, 192, 193, the first electrode 191 and second electrode 192 are formed on top of the plurality of ridge wave guides 161, 162, 163. Furthermore, the first electrode 191 is formed on top of the second ridge wave guide 162 such that it extends to the top of the third ridge wave guide 163, and the second electrode 192 is formed on top of the first ridge wave guide 161 such that it extends to the top of the second ridge wave guide 162. Herein, the first electrode 191 and second electrode 192 are formed such that they are spaced from each other. The third electrode 193 is formed on top of the substrate 110.

On a distributed bragg reflector ridge laser diode according to an embodiment of the present invention, light may be output to both directions, and for embodiment of smooth oscillation characteristics, on a side of an axial direction (z axis) of where the first core layer 131 is formed, an anti-reflector coating film (not illustrated) may be further formed.

Furthermore, on a side of an axial direction (z axis) of where the second core layer 133 is formed, a coating film having a predetermined reflectivity may be formed. Herein, the reflectivity of the coating film may be 30%.

Hereinbelow, a method for fabricating a distributed bragg reflector ridge laser diode according to an embodiment of the present invention will be explained.

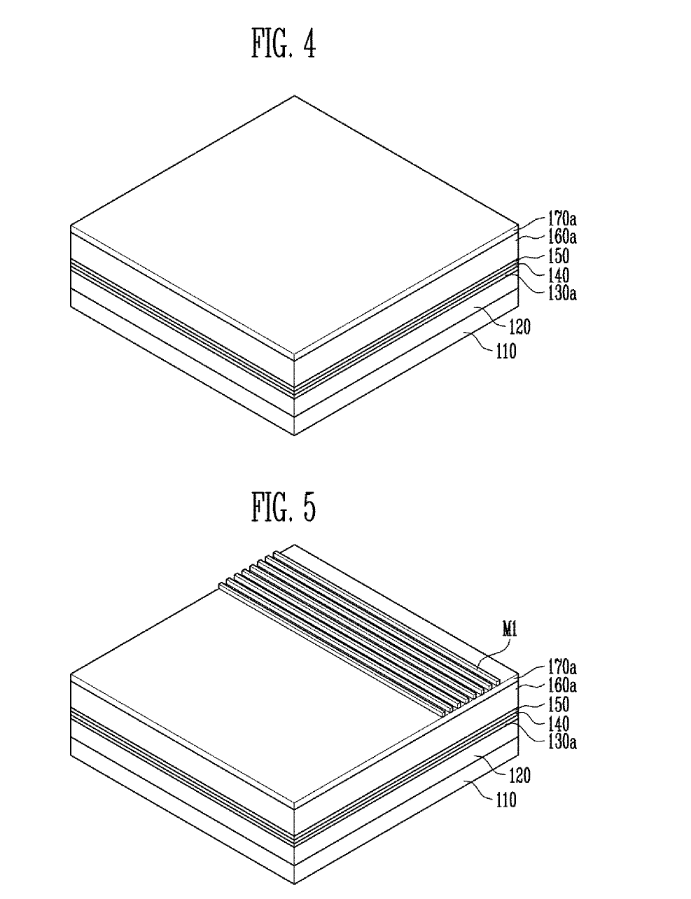

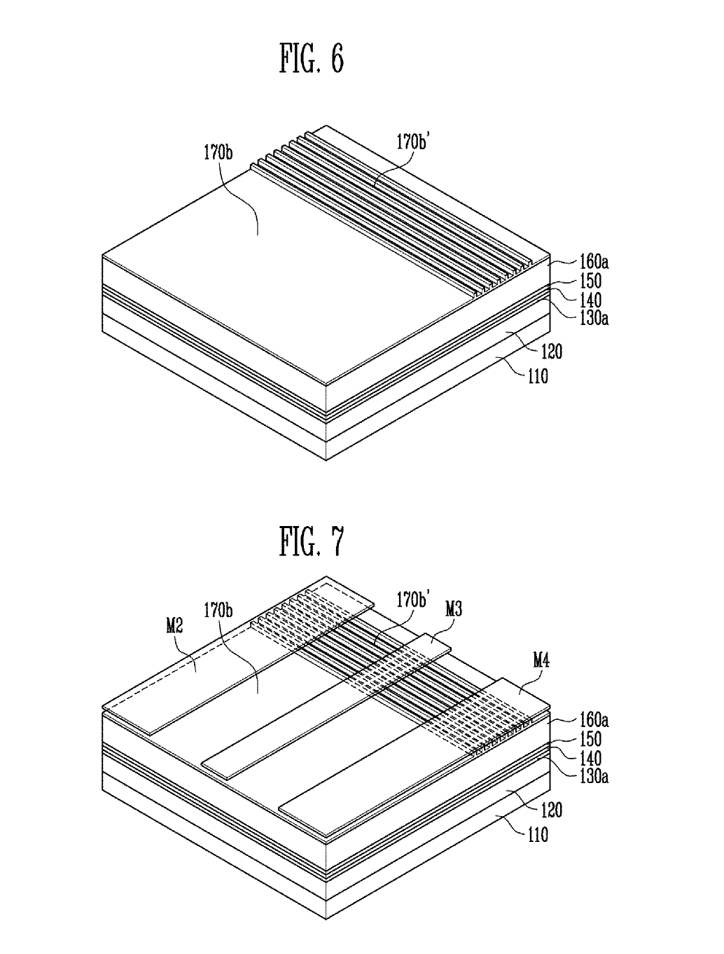

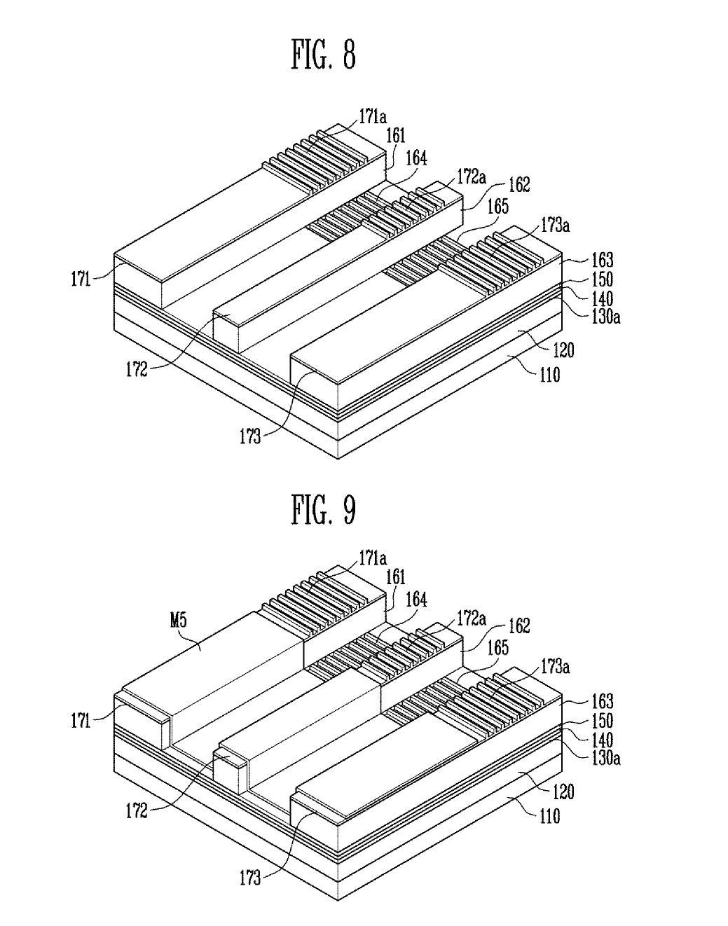

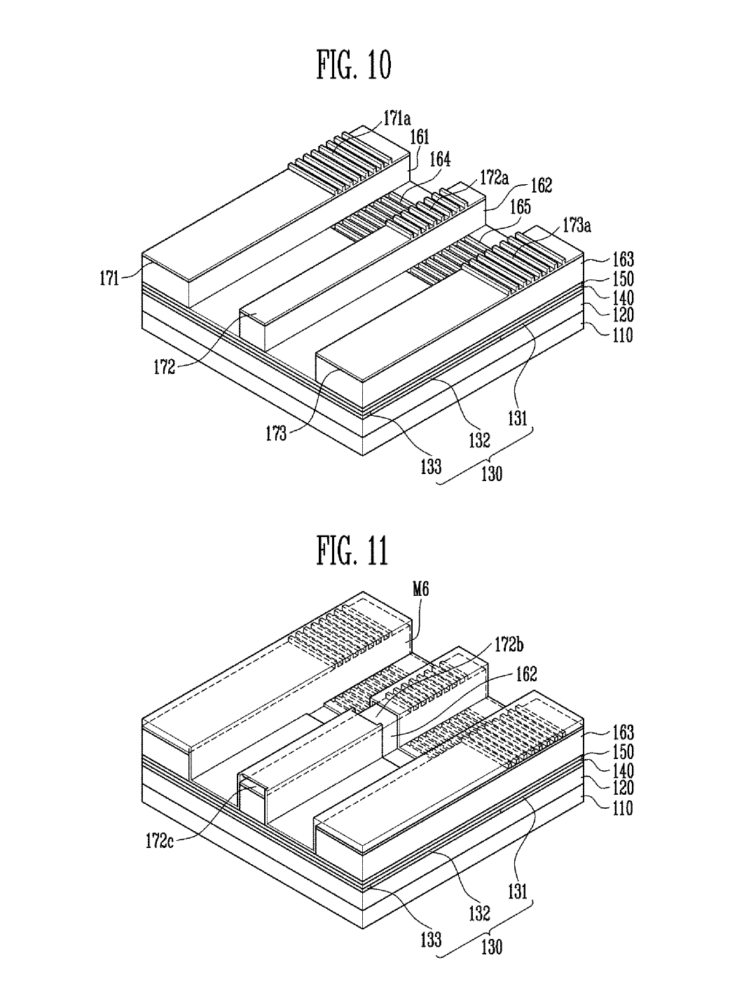

FIG. 3 is a flowchart for explaining a method for fabricating a distributed bragg reflector ridge laser diode according to an embodiment of the present invention. FIGS. 4 to 13 are views for explaining a method for fabricating a distributed bragg reflector ridge laser diode according to an embodiment of the present invention.

Referring to FIGS. 3 and 4, according to the method for fabricating a distributed bragg reflector ridge laser diode, a lower clad layer 120 is formed on top of a substrate 110, an MQW (Multiple Quantum Well) layer 130a, that is an active core zone is formed on top of the lower clad layer 120 so as to form a multilayer structure (S110). Herein, the MQW layer 130a may be a multiple quantum well layer that includes InGaP and AlGaInP. Furthermore, on top of the MQW layer 130a, a middle clad layer 140, etching stopping layer 150, upper clad layer 160a, and preliminary contact layer 170a may be further laminated successively.

Furthermore, referring to FIGS. 3, 5, and 6, a grating 170b′ of a grating shape is formed (S120). More specifically, on top of the preliminary contact layer 170a, an insulating film mask M1 having a grating shape and made of SiO₂ material or SiNₓ material is disposed, and an upper portion of the preliminary contact layer 170a is partially etched to form an etching contact layer 170b and grating 170b′. Herein, according to the degree of precision of the pattern of the insulating film mask M1, one of a contact aligner, stepper, and E-beam may be used.

Furthermore, referring to FIGS. 3, 7, and 8, on top of the MQW layer 130a, that is the active core zone, a plurality of ridge wave guides 161, 162, 163 are formed such that they are spaced from one another and extend in an axial direction (S130). More specifically, on top of the etching contact layer 170b and grating 170b′, a plurality of masks M2, M3, M4 are disposed to correspond to shapes of the plurality of ridge wave guides 161, 162, 163 that will be formed later. Furthermore, the etching contact layer 170b, grating 170b′, and upper clad layer 160a are etched to form a plurality of ridge wave guides 161, 162, 163 and plurality of contact layers 171, 172, 173. Herein, a plurality of diffraction gratings 164, and 165 are formed as well.

Furthermore, referring to FIGS. 3, 9, and 10, the MQW layer 130a, that is the active core zone is divided into a first core layer 131, active zone 132 and second core layer 133 (S140). Herein, a mask M5 is formed on top of the plurality of ridge wave guides 161, 162, 163 and etching stopping layer 150 such that it has a shape corresponding to the shape of the active zone 132 to be formed. Furthermore, a material having a greater band gap than the active zone 132 is injected into the MQW layer 130a to form a first core layer 131 and second core layer 133. Herein, Zn defusion (18 mg solid Zn₃As₂ alloy, furnace Celsius temperature 480-580 degrees) may be utilized, and the defusion time may be adjusted to embody a band gap wavelength change of 40 nm or more.

Furthermore, referring to FIG. 11, the second contact layer 172 is etched using the mask M6 to form a separating area 172b and COD (Catastrophic Optical Damage) area 172c. The etching may be wet etching that reacts only to GaAs. Herein, the separating area 172b plays the role of electrically separating a gain area and DBR area. Furthermore, the COD area 172c is formed on top of the second core layer 133 to prevent a cross-section of an element from being destructed during a high powered output.

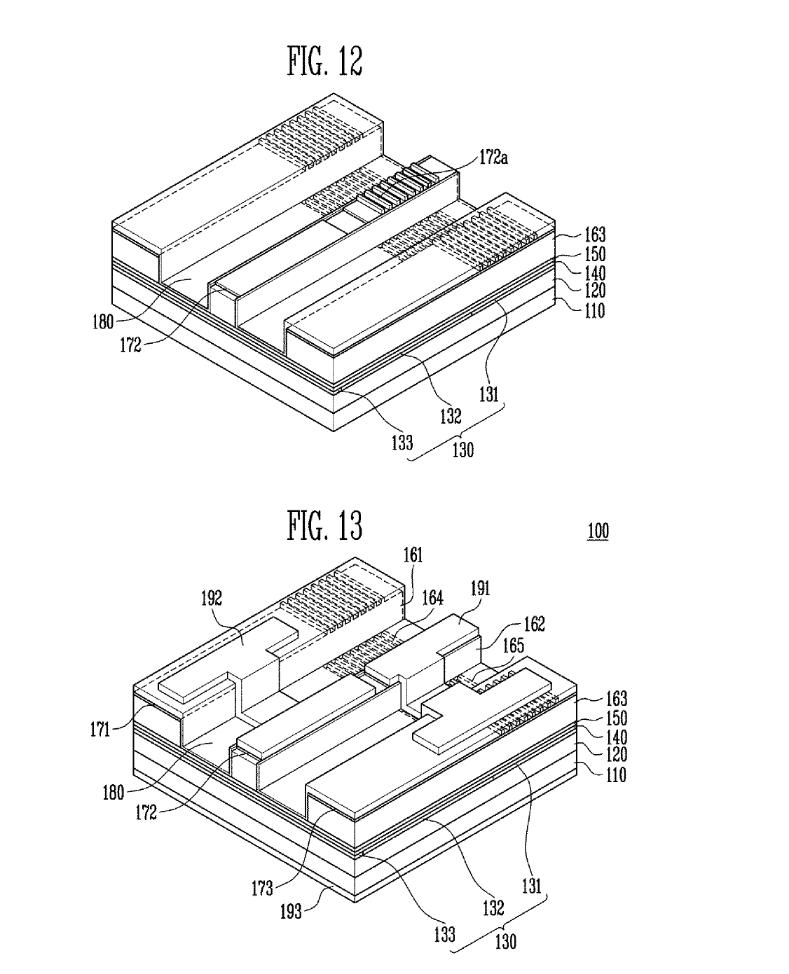

Furthermore, referring to FIGS. 3 and 12, on top of the plurality of ridge wave guides 161, 162, 163, plurality of diffraction gratings 164, 165, and etching stopping layer 150, the passivation layer 180 is formed (S150).

Then, referring to FIGS. 3 and 13, on top of the plurality of ridge wave guides 161, 162, 163 and below the substrate 110, a plurality of electrodes 191, 192, 193 are formed (S160). Herein, the first electrode 191 and second electrode 192 are electrically insulated from each other by the separating area 172b. Furthermore, the plurality of electrodes 191, 192, 193 may be formed in a pad metal process.

Furthermore, there may be further included a step of forming a coating layer (not illustrated) having a predetermined reflectivity on a side of an axial direction of where the second core layer 133 is formed. Herein, the reflectivity of the coating film may be 30%.

Furthermore, there may be further included a step of forming an anti-reflector coating layer (not illustrated) on a side of an axial direction of where the first core layer 131 is formed.

In the drawings and specification, there have been disclosed typical exemplary embodiments of the invention, and although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

1. A distributed bragg reflector ridge laser diode comprising:
a lower clad layer formed on top of a substrate;
an active core zone formed on top of the lower clad layer;
a plurality of ridge wave guides formed on top of the active core zone such that they are spaced from one another and extend in an axial direction;
a grating formed on top of the plurality of ridge wave guides;
a diffraction grating formed on top of the active core zone and between the plurality of ridge wave guides on a location corresponding to a location of the grating;
wherein:
the active core zone comprises a first core layer, an active zone, and a second core layer formed successively in the axial direction, the first and second core layers being made of a material having a greater band gap than the active zone; and
the distributed bragg reflector ridge laser diode, taken from a plan view, includes a first region, a second region and a third region successively arranged side by side, such that the first core layer, the diffraction grating and the grating are in the first region, the active zone is in the second region, and the second core layer in the third region.

2. The distributed bragg reflector ridge laser diode according to claim 1,
wherein an etching stopping layer is formed on top of the active core zone, and the plurality of ridge wave guides and the diffraction grating are formed on top of the etching stopping layer.

3. The distributed bragg reflector ridge laser diode according to claim 2,
wherein a middle clad layer is formed between the active core zone and etching stopping layer.

4. The distributed bragg reflector ridge laser diode according to claim 1,
further comprising a contact layer formed on top of the plurality of ridge wave guides.

5. The distributed bragg reflector ridge laser diode according to claim 4,
wherein the contact layer comprises the grating.

6. (canceled)

7. The distributed bragg reflector ridge laser diode according to claim 1,
wherein a COD (Catastrophic Optical Damage) area is formed on top of at least one of the plurality of ridge wave guides corresponding to the location of the second core layer.

8. The distributed bragg reflector ridge laser diode according to claim 1,
wherein an anti-reflector coating film is formed on a side of an axial direction of where the first core layer is formed.

9. The distributed bragg reflector ridge laser diode according to claim 1,
wherein a coating film having a predetermined reflectivity is formed on a side of an axial direction of where the second core layer is formed.

10. The distributed bragg reflector ridge laser diode according to claim 1,
wherein an electrode is formed on top of the plurality of ridge wave guides and a further electrode is formed below the substrate.

11. A method for fabricating a distributed bragg reflector ridge laser diode, the method comprising:
forming a lower clad layer on top of a substrate, and forming an active core zone on top of the lower clad layer to form a multilayer structure;
forming a plurality of ridge wave guides on top of the active core zone such that they are spaced from one another and extend in an axial direction;
forming a grating formed on top of the plurality of ridge wave guides;
forming a diffraction grating between the plurality of ridge wave guides on top of the active core zone on a location corresponding to a location of the grating;
wherein:
the active core zone comprises a first core layer, an active zone, and a second core layer formed successively in the axial direction, the first and second core layers being made of a material having a greater band gap than the active zone, the material being injected after the forming of the ridge wave guide and after the forming of the diffraction grating; and
the distributed bragg reflector ridge laser diode, taken from a plan view, includes a first region, a second region and a third region successively arranged side by side, such that the first core layer, the diffraction grating and the grating are in the first region, the active zone is in the second region, and the second core layer in the third region.

12. (canceled)

13. The method according to claim 11,
wherein a COD (Catastrophic Optical Damage) area is formed on top of at least one of the plurality of ridge wave guides corresponding to the location of the second core layer.

14. The method according to claim 11,
further comprising forming an anti-reflector coating film on a side of an axial direction of where the first core layer is formed.

15. The method according to claim 11,
further comprising forming a coating film having a predetermined reflectivity on a side of an axial direction of where the second core layer is formed.

16. The method according to claim 11,
wherein the forming of the ridge wave guide and the forming of the diffraction grating are performed at the same time.

17. The method according to claim 11,
wherein the forming of the ridge wave guide and the forming of the diffraction grating comprise:
forming an etching stopping layer on top of the active core zone;
forming an upper clad layer on top of the etching stopping layer;
forming a contact layer on top of the upper clad layer;
forming the grating on top of the contact layer; and
forming the ridge wave guide and the diffraction grating by etching the grating, contact layer, and upper clad layer.

18. The method according to claim 17,
further comprising forming a middle clad layer on top of the active core zone prior to the forming of the etching stopping layer.

19. The method according to claim 17,
further comprising forming a passivation layer on top of the ridge wave guide and diffraction grating.

20. The method according to claim 11,
further comprising forming an electrode on top of the plurality of ridge wave guides and a further electrode below the substrate.

21. The distributed bragg reflector ridge laser diode according to claim 2, wherein each of the plurality of ridge wave guides has a sidewall in direct contact with the etching stopping layer.

22. The method according to claim 17, wherein each of the plurality of ridge wave guides has a sidewall in direct contact with the etching stopping layer.
